(19) United States
(12) Patent Application Publication
(10) Pub. No.: US 2026/0107657 A1
(43) Pub. Date: Apr. 16, 2026

(54) DISPLAY PANEL, MANUFACTURING METHOD THEREFOR AND DISPLAY DEVICE

(71) Applicant: BOE Technology Group Co., Ltd., Beijing (CN)

(72) Inventor: Mingche HSIEH, Beijing (CN)

(73) Assignee: BOE Technology Group Co., Ltd., Beijing (CN)

(21) Appl. No.: 19/114,464

(22) PCT Filed: Jan. 2, 2024
(86) PCT No.: PCT/CN2024/070227

§ 371 Date: Mar. 24, 2025

(30) Foreign Application Priority Data
Jan. 17, 2023 (CN) 202310078388.6

(51) Int. Cl. H10K 59/65; H10K 59/12; H10K 59/122; H10K 59/80

(52) U.S. Cl. CPC H10K 59/65; H10K 59/1201; H10K 59/122; H10K 59/8792

(57) ABSTRACT

The present disclosure provides a display panel, including: a light-transmitting area, including a plurality of first pixel units, wherein a light-transmitting hole is provided between two adjacent first pixel units, and a hole wall of the light-transmitting hole is provided with a light-absorbing structure; and a display area, located outside the light-transmitting area and including a plurality of second pixel units, wherein a distribution density of the second pixel units in the display area is greater than a distribution density of the first pixel units in the light-transmitting area.

### CROSS-REFERENCE TO RELATED APPLICATIONS

The present application is a U.S. National Stage Application of International Application No. PCT/CN2024/070227, filed on Jan. 2, 2024, which is based upon and claims the priority to the Chinese Patent Application NO. 202310078388.6, entitled “DISPLAY PANEL, MANUFACTURING METHOD THEREOF, AND DISPLAY DEVICE”, filed on Jan. 17, 2023, the entire contents of each are hereby incorporated by reference.

### TECHNICAL FIELD

The present disclosure relates to the field of display technologies, and in particular, to a display panel and a manufacturing method thereof, and a display device.

### BACKGROUND

With the development of the market, consumers have increasingly stringent requirements for display effects of display screens, requiring not only diversified appearance designs, but also a higher screen-to-body ratio. Full-screen technologies achieve a screen-to-body ratio of more than 90% through ultra-narrow border or even borderless designs.

The full-screen design maximizes a display area without changing the body, making the display effect even more amazing. In the existing full-screen based structural design, in order to install devices such as camera modules, a display area with a light-transmitting area is provided on the top of the display substrate to ensure that light can pass through the light-transmitting area to reach the camera module while the display function is met.

It should be noted that the information disclosed in the Background section above is only for enhancing the understanding of the background of the present disclosure, and thus may include information that does not constitute prior art known to those of ordinary skill in the art.

### SUMMARY

According to an aspect of the present disclosure, there is provided a display panel, including:
a light-transmitting area, provided with a plurality of first pixel units, wherein a light-transmitting hole is provided between two adjacent first pixel units, and a hole wall of the light-transmitting hole is provided with a light-absorbing structure; and
a display area, located outside the light-transmitting area and provided with a plurality of second pixel units, wherein a distribution density of the second pixel units in the display area is greater than a distribution density of the first pixel units in the light-transmitting area.

According to an aspect of the present disclosure, there is provided a method for manufacturing a display panel, wherein the display panel includes a light-transmitting area and a display area, and the method includes:
manufacturing a substrate, wherein the substrate is provided with a first through hole located in the light-transmitting area;
manufacturing a driving layer on a side of the substrate, wherein the driving layer is provided with a second through hole located in the light-transmitting area, a hole wall of the second through hole is provided with a first sub-light-absorbing structure, and a surface of the first sub-light-absorbing structure is at most flush with a hole edge of the first through hole on a side away from the driving layer;
manufacturing a light-emitting layer on a side of the driving layer away from the substrate, wherein the light-emitting layer is provided with a third through hole located in the light-transmitting area, and a hole wall of the third through hole is at most flush with a surface of the first sub-light-absorbing structure; and
manufacturing a functional film layer on a side of the light-emitting layer away from the substrate, wherein the functional film layer is provided with a fourth through hole located in the light-transmitting area, a hole wall of the fourth through hole is provided with a second sub-light-absorbing structure, and a surface of the second sub-light-absorbing structure is at most flush with the hole wall of the third through hole.

According to an aspect of the present disclosure, there is provided a display device, including the display panel according to any aspect.

It should be noted that the above general description and the following detailed description are merely exemplary and explanatory and should not be construed as limiting of the disclosure.

### BRIEF DESCRIPTION OF THE DRAWINGS

The drawings herein are incorporated in and constitute a part of the specification, illustrate embodiments consistent with the present disclosure, and together with the description serve to explain principles of the present disclosure. Apparently, the drawings in the following description are only some embodiments of the present disclosure. For those of ordinary skill in the art, other drawings may be obtained based on these drawings without paying any creative effort.

FIG. 1 is a schematic diagram of a partial top view structure of a display panel provided in an embodiment of the present disclosure.

FIG. 2 is a schematic diagram of a cross-sectional structure of a light-transmitting area of a display panel provided in an embodiment of the present disclosure.

FIG. 3 is a schematic diagram of a cross-sectional structure of a light-transmitting area of a display panel provided in an embodiment of the present disclosure.

FIG. 4 is a schematic diagram of a cross-sectional structure of a light-transmitting area of a display panel provided in an embodiment of the present disclosure.

FIG. 5 is a schematic diagram of a cross-sectional structure of a light-transmitting area of a display panel provided in an embodiment of the present disclosure.

FIG. 6 is a schematic diagram of a cross-sectional structure of a light-transmitting area of a display panel provided in an embodiment of the present disclosure.

FIG. 7 is a schematic diagram of a cross-sectional structure of a light-transmitting area of a display panel provided in an embodiment of the present disclosure.

FIG. 8 is a schematic flowchart of a manufacturing process of a display panel provided in an embodiment of the present disclosure.

FIG. 9 is a schematic diagram of a cross-sectional structure of a display panel during a manufacturing process provided in an embodiment of the present disclosure.

FIG. 10 is a schematic diagram of a cross-sectional structure of a display panel during a manufacturing process provided in an embodiment of the present disclosure.

FIG. 11 is a schematic diagram of a cross-sectional structure of a display panel during a manufacturing process provided in an embodiment of the present disclosure.

FIG. 12 is a schematic diagram of a cross-sectional structure of a display panel during a manufacturing process provided in an embodiment of the present disclosure.

FIG. 13 is a schematic diagram of a cross-sectional structure of a display panel during a manufacturing process provided in an embodiment of the present disclosure.

FIG. 14 is a schematic diagram of a cross-sectional structure of a display panel during a manufacturing process provided in an embodiment of the present disclosure.

FIG. 15 is a schematic diagram of a cross-sectional structure of a display panel during a manufacturing process provided in an embodiment of the present disclosure.

FIG. 16 is a schematic diagram of a cross-sectional structure of a display panel during a manufacturing process provided in an embodiment of the present disclosure.

FIG. 17 is a schematic diagram of a cross-sectional structure of a display panel during a manufacturing process provided in an embodiment of the present disclosure.

FIG. 18 is a schematic diagram of a cross-sectional structure of a display panel during a manufacturing process provided in an embodiment of the present disclosure.

FIG. 19 is a schematic diagram of a cross-sectional structure of a display panel during a manufacturing process provided in an embodiment of the present disclosure.

FIG. 20 is a schematic diagram of a cross-sectional structure of a display panel during a manufacturing process provided in an embodiment of the present disclosure.

FIG. 21 is a schematic diagram of a cross-sectional structure of a display panel during a manufacturing process provided in an embodiment of the present disclosure.

FIG. 22 is a schematic diagram of a cross-sectional structure of a display panel during a manufacturing process provided in an embodiment of the present disclosure.

FIG. 23 is a schematic diagram of a cross-sectional structure of a display panel during a manufacturing process provided in an embodiment of the present disclosure.

FIG. 24 is a schematic diagram of a cross-sectional structure of a display panel during a manufacturing process provided in an embodiment of the present disclosure.

FIG. 25 is a schematic diagram of a cross-sectional structure of a display panel during a manufacturing process provided in an embodiment of the present disclosure.

FIG. 26 is a schematic diagram of a cross-sectional structure of a display panel during a manufacturing process provided in an embodiment of the present disclosure.

FIG. 27 is a schematic diagram of a cross-sectional structure of a display panel during a manufacturing process provided in an embodiment of the present disclosure.

FIG. 28 is a schematic diagram of a cross-sectional structure of a display panel provided in an embodiment of the present disclosure.

### DETAILED DESCRIPTION

Example embodiments will now be described more fully with reference to the accompanying drawings. However, the example embodiments can be implemented in a variety of forms and should not be construed as being limited to examples set forth herein; rather, these embodiments are provided so that the present disclosure will be more complete and comprehensive so as to convey the idea of the example embodiments to those skilled in this art. The same reference numerals in the drawings denote the same or similar structures, and the repeated description thereof will be omitted. In addition, the drawings are merely schematic representations of the present disclosure and are not necessarily drawn to scale.

The terms “one”, “a”, “the”, “said”, and “at least one” are used to indicate that there are one or more elements/components or the like; the terms “include” and “have” are used to indicate an open meaning of including and means that there may be additional elements/components/etc. in addition to the listed elements/components/etc.; and the terms “first”, “second” and “third” etc. are used only as markers, and do not limit the number of objects.

A transistor refers to an element that includes at least three terminals of a gate electrode, a drain electrode, and a source electrode. The transistor has a channel region between the drain electrode (also referred to as a drain electrode terminal or a drain region) and the source electrode (also referred to as a source electrode terminal or a source region). The channel region refers to a region where the current mainly flows, so that the current can flow through the drain electrode, the channel region, and the source electrode.

Generally, for a first electrode and a second electrode of a transistor, the first electrode may be the drain electrode and the second electrode may be a source electrode, or the first electrode may be the source electrode and the second electrode may be the drain electrode. In the case of using transistors with opposite polarities or when a current direction changes during circuit operation, functions of the “source electrode” and the “drain electrode” are sometimes interchanged. Therefore, in this specification, the “source electrode” and the “drain electrode” can be interchanged.

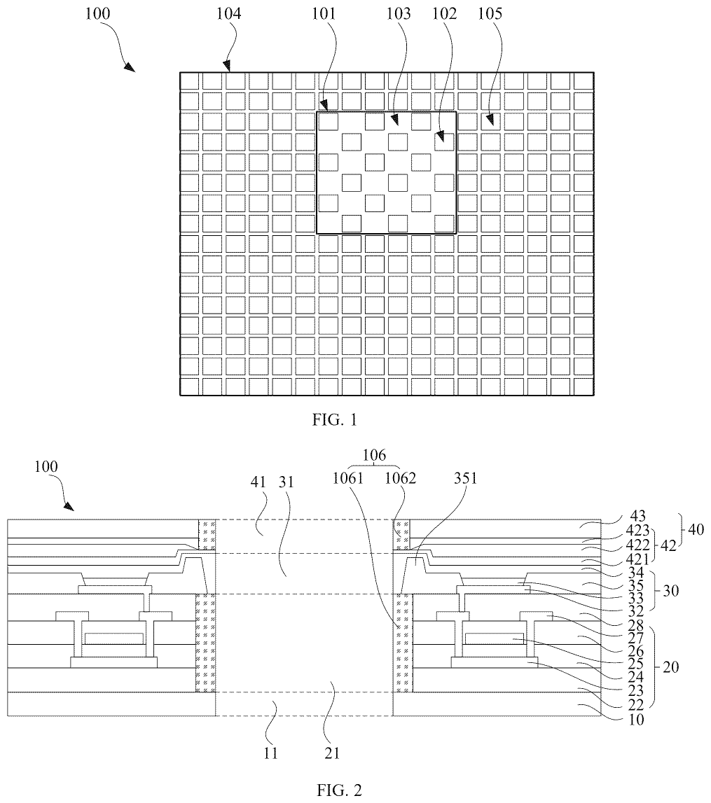

FIG. 1 illustrates a schematic diagram of a partial top view structure of a display panel 100 provided in an embodiment of the present disclosure, and FIG. 2 illustrates a schematic diagram of a cross-sectional structure of a display panel 100 provided in an embodiment of the present disclosure. As shown in FIG. 1 and FIG. 2, the display panel 100 includes a light-transmitting area 101 and a display area 104. The light-transmitting area 101 has a plurality of first pixel units 102, a light-transmitting hole 103 is provided between two adjacent first pixel units 102, and a hole wall of the light-transmitting hole 103 has a light-absorbing structure 106. The display area 104 is located outside the light-transmitting area 101, and has a plurality of second pixel units 105. A distribution density of the second pixel units 105 in the display area 104 is greater than a distribution density of the first pixel units 102 in the light-transmitting area 101.

In embodiments of the present disclosure, for the light-transmitting area 101 included in the display panel 100, the first pixel units 102 are provided in the light-transmitting area 101, and the light-transmitting hole 103 is provided between the two adjacent first pixel units 102, so that light can pass through the light-transmitting hole 103 to realize the under-screen camera function of the display panel 100 while the full-screen display of the display panel 100 is ensured. When the light passes through the light-transmitting hole 103, since the hole wall of the light-transmitting hole 103 is provided with the light-absorbing structure 106, the stray light generated after the light is reflected by the hole wall of the light-transmitting hole 103 can be reduced, so as to ensure the light-transmitting effect of the light-transmitting hole 103, thereby improving the clarity of the image when the camera module is shooting.

In some embodiments, the display panel 100 further includes a light-transmitting film layer 50 at least located on a display side of the display panel 100, and the light-transmitting film layer 50 covers the light-transmitting hole 103. In this way, by providing the light-transmitting film layer 50, the light-transmitting hole 103 on the display panel 100 can be protected to prevent foreign matter, water, oxygen, etc. from entering the light-transmitting hole 103 to damage the display panel 100 and shorten the service life of the display panel 100.

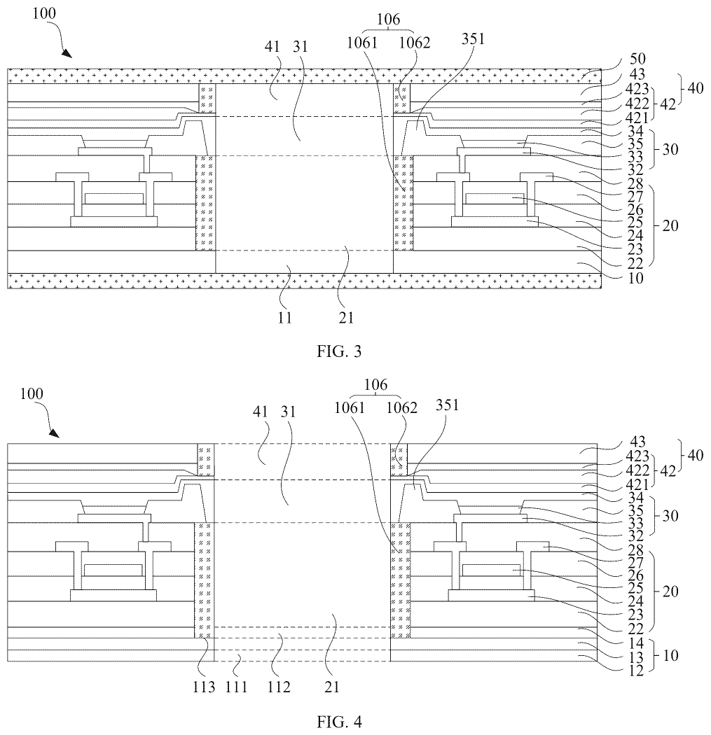

In some embodiments, as shown in FIG. 3, both the display side and a backlight side of the display panel 100 have light-transmitting film layers 50, and the light-transmitting film layers 50 on both sides cover the light-transmitting hole 103 of the light-transmitting area 101.

In addition to blocking the light-transmitting hole 103, the light-transmitting film layer 50 also needs to ensure the transmittance of light to avoid affecting the light transmission efficiency along the light-transmitting hole 103. For example, the light-transmitting film layer 50 may be a transparent film.

In embodiments of the present disclosure, the light-absorbing structure 106 provided on the hole wall of the light-transmitting hole 103 may be a light-absorbing structure 106 separately manufactured on the hole wall of the light-transmitting hole 103 after the manufacturing of the display panel 100 with the light-transmitting hole 103 is completed, or a light-absorbing structure 106 formed on the hole wall of the light-transmitting hole 103 during the process of manufacturing the display panel 100 with the light-transmitting hole 103.

When the light-absorbing structure 106 is formed during the process of manufacturing the display panel 100, it may be described in conjunction with a film layer structure of the display panel 100. Next, the film layer structure of the display panel 100 is explained in detail.

In some embodiments, as shown in FIG. 2 or FIG. 4, the display panel 100 includes a substrate 10, a driving layer 20, and a light-emitting layer 30. The driving layer 20 is located on a side of the substrate 10 and is provided with a plurality of pixel circuits. The light-emitting layer 30 is located on a side of the driving layer 20 away from the substrate 10 and is provided with a plurality of light-emitting devices. A pixel circuit is connected to at least one corresponding light-emitting device (for example, one pixel circuit is connected to one corresponding light-emitting device). In this way, the corresponding light-emitting device can be driven by the pixel circuit to emit light, thereby realizing the display of the picture.

A material of the substrate 10 may be an inorganic material or an organic material. For example, in some embodiments, the material of the substrate 10 may be a glass material such as so-lime glass, quartz glass, sapphire glass, or a metal material such as stainless steel, aluminum, nickel, etc. In some other embodiments, the material of the substrate 10 may be polymethyl methacrylate (PMMA), polyvinyl alcohol (PVA), polyvinyl phenol (PVP), polyether sulfone (PES), polyimide, polyamide, polyacetal, poly carbonate (PC), polyethylene terephthalate (PET), polyethylene naphthalate (PEN), or a combination thereof.

In addition to a single layer of material, the substrate 10 may be a composite of multiple layers of materials. For example, in some embodiments, as shown in FIG. 4, the substrate 10 includes a first polyimide layer 12, a protective film layer 13, and a second polyimide layer 14 stacked in sequence in a direction close to the driving layer 20.

In some embodiments, as shown in FIG. 2 or FIG. 4, the driving layer 20 includes: a buffer layer 22, an active layer 23, a gate insulation layer 24, a gate metal layer 25, an interlayer insulation layer 26, a source-drain metal layer 27, and a planar layer 28, which are stacked in sequence in a direction away from the substrate 10.

The active layer 23 may be a polysilicon layer, or an oxide film layer, or another structural layer, as long as it can form the channel region of the transistor and two connection portions (with conductive properties) located on both sides of the channel region, which is not limited by embodiments of the present disclosure.

The gate metal layer 25 and the source-drain metal layer 27 may be a single-layer structure or a multi-layer structure. For example, the gate metal layer 25 includes a first gate metal layer 25 and a second gate metal layer 25, and/or the source-drain metal layer 27 includes a first source-drain metal layer 27 and a second source-drain metal layer 27. When the gate metal layer 25 is the multi-layer structure and the source-drain metal layer 27 is the multi-layer structure, the number of layers of the gate insulation layer 24 and the planar layer 28 will be adjusted accordingly, which is not limited by the present disclosure.

In some embodiments, the plurality of light-emitting devices of the light-emitting layer 30 are distributed in an array and can be divided into a plurality of light-emitting units, each of which includes a plurality of light-emitting devices emitting different colors. For example, a light-emitting unit may include a red light-emitting device emitting red light, a green light-emitting device emitting green light, and a blue light-emitting device emitting blue light.

In some embodiments, the light-emitting device is an organic light-emitting diode (OLED), as shown in FIG. 2 or FIG. 4, which includes a first electrode 32, a light-emitting function layer 33, and a second electrode 34 sequentially stacked in a direction away from the substrate 10.

The first electrode 32 may be provided on a side of the driving layer 20 away from the substrate 10, and connected to the corresponding pixel circuit. The light-emitting function layer 33 may include a hole injection layer, a hole transport layer, a composite light-emitting layer 30, an electron transport layer and an electron injection layer stacked in sequence in the direction away from the substrate 10. In addition, an electron blocking layer may be provided between the hole transport layer and the composite light-emitting layer 30. The second electrode 34 covers the light-emitting function layer 33, and second electrodes 34 of the plurality of light-emitting devices may share an electrode layer.

In embodiments of the present disclosure, as shown in FIG. 2 or FIG. 4, the light-emitting layer 30 includes a pixel definition layer 35, and the pixel definition layer 35 may be made of a light shielding material. For example, the material of the pixel definition layer 35 may be black photoresist.

The pixel definition layer 35 is located on a side of the first electrode 32 away from the substrate 10, and is provided with pixel openings in a one-to-one correspondence with the plurality of first electrodes 32. The first electrode 32 includes an exposed area exposed at the corresponding pixel opening and a covered area covered by the pixel definition layer 35. The exposed area of the first electrode 32 forms the light-emitting area of the corresponding light-emitting device.

In some embodiments, the display panel 100 further includes a function layer, such as a thin film encapsulation layer 42, a black matrix layer, a color film layer, a touch function layer 43, and the like.

As shown in FIG. 2 or FIG. 4, the display panel 100 includes the thin film encapsulation layer 42, which is located on the side of the light-emitting layer 30 away from the substrate 10 to cover the light-emitting devices included in the light-emitting layer 30, thereby protecting the light-emitting device to prevent external water and oxygen from corroding the light-emitting devices.

The thin film encapsulation layer 42 may include an inorganic encapsulation layer and an organic encapsulation layer 422 that are alternately stacked. The inorganic encapsulation layer can effectively block external moisture and oxygen, and prevent water and oxygen from invading the organic light-emitting function layer 33 to cause material degradation. The organic encapsulation layer 422 is located between two adjacent inorganic encapsulation layers to achieve planarization and reduce stress between the inorganic encapsulation layers.

The display panel 100 has the display area 104 and a peripheral area located outside the display area 104. An edge of the inorganic encapsulation layer may be located in the peripheral area, and an edge of the organic encapsulation layer 422 may be located between an edge of the display area 104 and an edge of the inorganic encapsulation layer. For example, the thin film encapsulation layer 42 includes a first inorganic encapsulation layer 421, an organic encapsulation layer 422, and a second inorganic encapsulation layer 423 sequentially stacked on the side of the light-emitting layer 30 away from the substrate 10.

As shown in FIG. 2 or FIG. 4, the display panel 100 further includes the touch function layer 43 located on a side of the thin film encapsulation layer 42 away from the substrate 10 to implement a touch operation on the display panel 100.

In combination with the display panel 100 described above, in some embodiments, the display panel 100 includes the substrate 10, the driving layer 20, the light-emitting layer 30, and a functional film layer 40. In this case, as shown in FIG. 2, FIG. 3 or FIG. 4, the substrate 10 has a first through hole 11 located in the light-transmitting area 101; the driving layer 20 has a second through hole 21 located in the light-transmitting area 101, a hole wall of the second through hole 21 has a first sub-light-absorbing structure 1061, and a surface of the first sub-light-absorbing structure 1061 is at most flush with a hole edge of the first through hole 11 on a side away from the driving layer 20; the light-emitting layer 30 has a third through hole 31 located in the light-transmitting area 101, and a hole wall of the third through hole 31 is at most flush with the surface of the first sub-light-absorbing structure 1061; and the functional film layer 40 has a fourth through hole 41 located in the light-transmitting area 101, a hole wall of the fourth through hole 41 has a second sub-light-absorbing structure 1062, and a surface of the second sub-light-absorbing structure 1062 is at most flush with the surface of the first sub-light-absorbing structure 1061.

In this way, when the light passes through the light-transmitting hole 103 of the light-transmitting area 101, it can be absorbed by the second sub-light-absorbing structure 1062 when reaching the hole wall of the fourth through hole 41, and can be absorbed by the first sub-light-absorbing structure 1061 when reaching the hole wall of the second through hole 21, to reduce the formation of stray light when the light passes through the light-transmitting hole 103, thereby ensuring the light transmission effect and in turn improving the clarity of the image when the under-screen camera module is shooting.

The first through hole 11 may be a through bore as shown in FIG. 2 or FIG. 3, or a stepped hole with a stepped surface 113 as shown in FIG. 4.

When the first through hole 11 is the through bore, an orthographic projection of the second through hole 21 in the driving layer 20 on the substrate 10 covers the first through hole 11, that is, the hole wall of the first through hole 11 protrudes beyond the hole wall of the second through hole 21, so as to form the first sub-light-absorbing structure 1061 on the hole wall of the second through hole 21 which is at most flush with the hole wall of the first through hole 11.

In some embodiments, the first sub-light-absorbing structure 1061 is supported on the substrate 10 to increase a distribution area of the first sub-light-absorbing structure 1061 in a thickness direction of the display panel 100, thereby maximizing the absorption of light reaching the hole wall of the second through hole 21.

When the first through hole 11 is the stepped hole, the stepped surface 113 of the first through hole 11 faces the driving layer 20. Combined with the above-mentioned case that the substrate 10 includes the first polyimide layer 12 and the second polyimide layer 14, as shown in FIG. 4, the first polyimide layer 12 has a first through hole 111, the second polyimide layer 14 has a second through hole 112, and an aperture of the first through hole 111 is smaller than an aperture of the second through hole 112.

The orthographic projection of the second through hole 21 on the substrate 10 covers the second through hole 112, that is, a hole wall of the second through hole 112 protrudes beyond the hole wall of the second through hole 21. Alternatively, the orthographic projection of the second through hole 21 on the substrate 10 completely coincides with the second through hole 112, that is, the hole wall of the second through hole 112 is flush with the hole wall of the second through hole 21. Alternatively, an edge of the orthographic projection of the second through hole 21 on the substrate 10 is located in the second through hole 112 and covers the first through hole 111, that is, the hole wall of the second through hole 21 protrudes beyond the hole wall of the second through hole 112, and a hole wall of the first through hole 111 protrudes beyond the hole wall of the second through hole 21, so as to form the first sub-light-absorbing structure 1061 on the hole wall of the second through hole 21 that is at most flush with the hole wall of the first through hole 111.

In some embodiments, as shown in FIG. 4, the first sub-light-absorbing structure 1061 is supported on the protective film layer 13 included on the substrate 10. Alternatively, the first sub-light-absorbing structure 1061 is supported on the first polyimide layer 12 to further increase the distribution area of the first sub-light-absorbing structure 1061 in the thickness direction of the display panel 100, so as to not only absorb the light reaching the hole wall of the second through hole 21, but also absorb the light reaching the hole wall of the second through hole 112, to further reduce the formation of stray light when the light passes through the light-transmitting hole 103.

In some embodiments of the present disclosure, for the above-mentioned first light-absorbing structure 1061 and second light-absorbing structure 1062, the first light-absorbing structure 1061 may be formed in the process of manufacturing the driving layer 20 with the second through hole 21, or the first light-absorbing structure 1061 may be formed in the process of manufacturing the light-emitting layer 30 with the third through hole 31, and the second light-absorbing structure 1062 is formed in the process of manufacturing the functional film layer 40 with the fourth through hole 41. Alternatively, both the first light-absorbing structure 1061 and the second light-absorbing structure 1062 may be formed in the process of manufacturing the functional film layer 40 with the fourth through hole 41. Alternatively, the first light-absorbing structure 1061 and the second light-absorbing structure 1062 may also be formed in other ways, which are not limited in embodiments of the present disclosure.

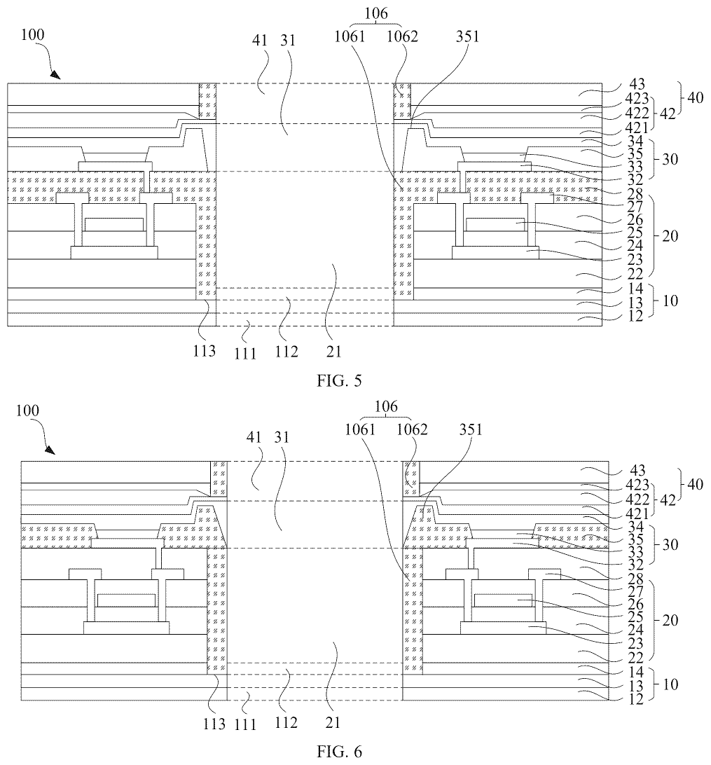

In the case where the first sub-light-absorbing structure 1061 is formed when the driving layer 20 with the second through hole 21 is manufactured, in combination with the film layer structure of the driving layer 20 as described above, the second through hole 21 sequentially penetrates the buffer layer 22, the gate insulation layer 24, the interlayer insulation layer 26, and the planar layer 28. In this case, as shown in FIG. 5, the planar layer 28 is a black material layer, and the planar layer 28 and the first sub-light-absorbing structure 1061 are manufactured in the same layer.

Since the first sub-light-absorbing structure 1061 is formed synchronously when the planar layer 28 is manufactured, the manufacturing process of the first sub-light-absorbing structure 1061 is simplified, thereby improving the manufacturing efficiency of the display panel 100. When the planar layer 28 is manufactured, the process of synchronously forming the first sub-light-absorbing structure 1061 can refer to the relevant technologies, which is not limited in embodiments of the present disclosure.

It should be noted that, in the case where the planar layer 28 includes the first sub-light-absorbing structure 1061, the light reaching the hole wall of the second through hole 21 can be absorbed by the first sub-light-absorbing structure 1061 included in the planar layer 28, and the light reaching the first pixel unit 102 in the light-transmitting area 101 can be absorbed by the planar layer 28 itself (i.e., the part covering the interlayer insulation layer 26), so as to further reduce the stray light generated on the backlight side of the display panel 100 and ensure the clarity of the image when the under-screen camera module is shooting.

In the case where the first sub-light-absorbing structure 1061 is formed when the light-emitting layer 30 with the third through hole 31 is manufactured, in combination with the film layer structure of the light-emitting layer 30 described above, the third through hole 31 sequentially penetrates the light-emitting function layer 33, the pixel definition layer 35, and the second electrode 34 layer. In this case, as shown in FIG. 6, the pixel definition layer 35 is a black material layer, and the pixel definition layer 35 and the first sub-light-absorbing structure 1061 are manufactured in the same layer.

Since the first sub-light-absorbing structure 1061 is formed synchronously when the pixel definition layer 35 is manufactured, the manufacturing process of the first sub-light-absorbing structure 1061 is simplified, thereby improving the manufacturing efficiency of the display panel 100. When the pixel definition layer 35 is manufactured, the process of synchronously forming the first sub-light-absorbing structure 1061 can refer to the relevant technologies, which is not limited in embodiments of the present disclosure.

In the case where the second sub-light-absorbing structure 1062 is formed when the functional film layer 40 with the fourth through hole 41 is manufactured, or both the first sub-light-absorbing structure 1061 and the second sub-light-absorbing structure 1062 are formed when the functional film layer 40 with the fourth through hole 41 is manufactured, in combination with the case where the functional film layer 40 includes the black matrix layer as described above, in this case, when the black matrix layer is manufactured, the second sub-light-absorbing structure 1062 is manufactured in the same layer, or the first sub-light-absorbing structure 1061 and the second sub-light-absorbing structure 1062 are manufactured in the same layer.

Since the second sub-light-absorbing structure 1062 is formed synchronously, or the first sub-light-absorbing structure 1061 and the second sub-light-absorbing structure 1062 are formed synchronously when the black matrix layer is manufactured, the manufacturing process of the first sub-light-absorbing structure 1061 and the second sub-light-absorbing structure 1062 is simplified, and the manufacturing efficiency of the display panel 100 is improved. When the black matrix layer is manufactured, the process of synchronously forming the second sub-light-absorbing structure 1062, or the first sub-light-absorbing structure 1061 and the second sub-light-absorbing structure 1062 can refer to the relevant technologies, which is not limited in embodiments of the present disclosure.

It should be noted that, since the film layer structure of the light-emitting layer 30 is simple, when the pixel definition layer 35 is the black material layer, the pixel definition layer 35 can also absorb the light reaching the hole wall of the third through hole 31, so as to further reduce the formation of stray light when the light passes through the light-transmitting hole 103. In addition, for the first sub-light-absorbing structure 1061 manufactured in the same layer as the pixel definition layer 35, since the pixel definition layer 35 has the pixel opening, in order to prevent the light from passing through the pixel opening to reach the backlight side of the display panel 100, a shielding layer may be provided between the substrate 10 and the driving layer 20 to absorb this part of the light. Alternatively, the planar layer 28 of the driving layer 20 may also be provided as a black material layer to absorb this part of the light, so as to further reduce the stray light reaching the backlight side of the display panel 100, thereby ensuring the clarity of the image when the under-screen camera module is shooting.

In some embodiments, in combination with the film layer structure of the driving layer 20 described above, at least one of the buffer layer 22, the gate insulation layer 24, the interlayer insulation layer 26, and the source-drain metal layer 27 included in the driving layer 20 includes a blocking structure formed on the hole wall of the second through hole 21 and surrounding the first sub-light-absorbing structure 1061. In this way, by forming the blocking structure, it is possible to effectively prevent water and oxygen from penetrating into the driving layer 20 along the hole wall of the second through hole 21, thereby effectively ensuring the performance of the pixel circuit in the driving layer 20 and extending the service life of the display panel 100.

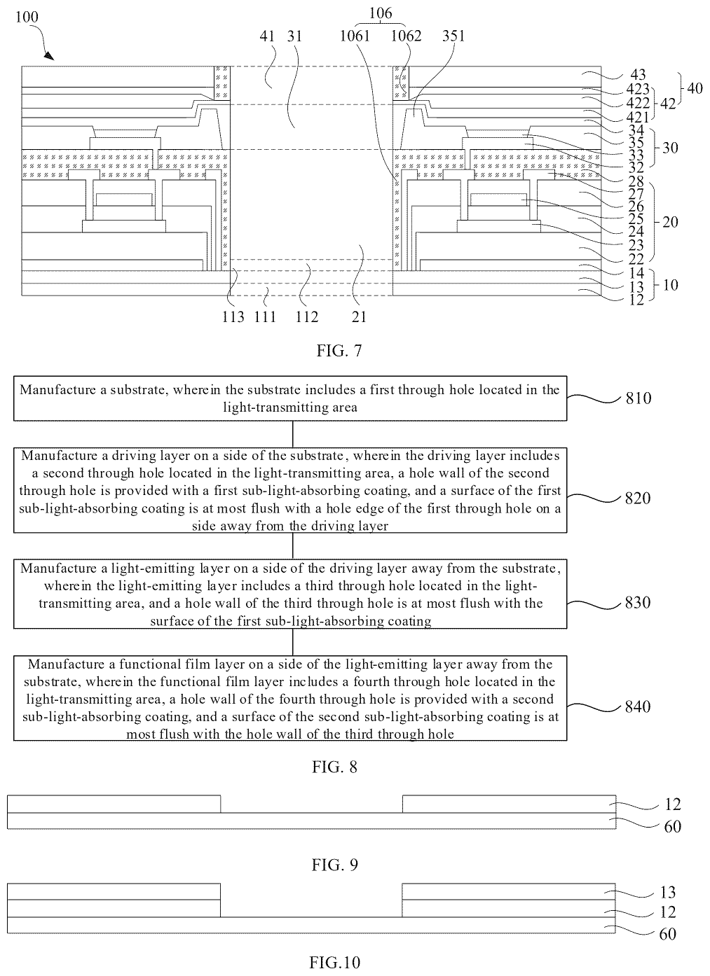

In combination with the above, when the first through hole 11 on the substrate 10 is the through bore, the blocking structure is supported on the substrate 10. Taking the buffer layer 22, the gate insulation layer 24, the interlayer insulation layer 26, and the source-drain metal layer 27 included in the driving layer 20 forming the blocking structure as an example, as shown in FIG. 7, the buffer layer 22 extends and covers the hole wall of the second through hole 112, the gate insulation layer 24 extends and covers the hole wall of the buffer layer 22, the interlayer insulation layer 26 extends and covers the hole wall of the gate insulation layer 24, and the source-drain metal layer 27 extends and covers the hole wall of the interlayer insulation layer 26.

When the first through hole 11 on the substrate 10 is the stepped hole with the stepped surface 113, the blocking structure is supported on the stepped surface 113 of the first through hole 11, that is, in combination with the film layer structure of the substrate 10 described above, the blocking structure is supported on the protective film layer 13, or supported on the first polyimide layer 12. Taking the buffer layer 22, the gate insulation layer 24, the interlayer insulation layer 26, and the source-drain metal layer 27 included in the driving layer 20 forming the blocking structure as an example, the buffer layer 22 extends and covers the hole wall of the second through hole 112, the gate insulation layer 24 extends and covers the hole wall of the buffer layer 22, the interlayer insulation layer 26 extends and covers the hole wall of the gate insulation layer 24, and the source-drain metal layer 27 extends and covers the hole wall of the interlayer insulation layer 26.

In some embodiments, in combination with the above-mentioned case where the light-emitting layer 30 includes the pixel definition layer 35, since the light-emitting layer 30 has the third through hole 31, when the thin film encapsulation layer 42 is manufactured on the side of the light-emitting layer 30 away from the substrate 10, in order to prevent the organic encapsulation layer 422 included in the thin film encapsulation layer 42 from flowing into the third through hole 31 during the leveling process, as shown in FIG. 7, the pixel definition layer 35 is provided with a convex ring 351 surrounding the second through hole 21, that is, the pixel definition layer 35 is provided with the convex ring 351 at an edge of the third through hole 31. In this way, through the formation of the convex ring 351, the organic encapsulation layer 422 can be blocked when the organic encapsulation layer 422 is leveled, thereby preventing the organic encapsulation layer 422 from flowing into the third through hole 31.

Embodiments of the present disclosure provide a method for manufacturing a display panel 100, which is used to manufacture the display panel 100 with the light-transmitting area 101 and the display area 104 as described in the above embodiments.

As shown in FIG. 8, the method includes steps S810 to S840.

In the step S810, the substrate 10 is manufactured, and the substrate 10 has the first through hole 11 located in the light-transmitting area 101.

In the step S820, the driving layer 20 is manufactured on the side of the substrate 10, the driving layer 20 has the second through hole 21 located in the light-transmitting area 101, the hole wall of the second through hole 21 has the first sub-light-absorbing structure 1061, and the surface of the first sub-light-absorbing structure 1061 is at most flush with the hole edge of the first through hole 11 on the side away from the driving layer 20.

In the step S830, the light-emitting layer 30 is manufactured on the side of the driving layer 20 away from the substrate 10, the light-emitting layer 30 has the third through hole 31 located in the light-transmitting area 101, and the hole wall of the third through hole 31 is at most flush with the surface of the first sub-light-absorbing structure 1061.

In the step S840, the functional film layer 40 is manufactured on the side of the light-emitting layer 30 away from the substrate 10, the functional film layer 40 has the fourth through hole 41 located in the light-transmitting area 101, the hole wall of the fourth through hole 41 has the second sub-light-absorbing structure 1062, and the surface of the second sub-light-absorbing structure 1062 is at most flush with the hole wall of the third through hole 31.

In embodiments of the present disclosure, when the light passes through the light-transmitting area 101, the light reaching the hole wall of the second through hole 21 and the light reaching the hole wall of the fourth through hole 41 can be absorbed by the first sub-light-absorbing structure 1061 and the second sub-light-absorbing structure 1062 respectively, so as to reduce the formation of stray light, thereby ensuring the light transmission effect and further improving the clarity of the image when the under-screen camera module is shooting.

In the above step S810, the process of manufacturing the substrate 10 with the first through hole 11 may be: providing the substrate 10, and manufacturing, according to a prefabricated pattern of the substrate 10, the first through hole 11 located between two adjacent first pixel units 102, or separately manufacturing the substrate 10 with the first through hole 11 according to the prefabricated pattern of the substrate 10.

In the case of separately manufacturing the substrate 10 with the first through hole 11, a glass substrate 60 may be provided in advance, and the glass substrate 60 is used as a carrier to manufacture, on the glass substrate 60, the substrate 10 with the first through hole 11. Accordingly, after the manufacturing of the display panel 100 is completed, the glass substrate 60 may be peeled off from the substrate 10.

The first through hole 11 may be a through bore, or a hole with a stepped surface 113 (the substrate 10 is a composite film layer structure). In this case, the substrate 10 with the first through hole 11 may be formed by etching during the process of manufacturing the substrate 10 on the glass substrate 60.

Next, taking the substrate 10 as the composite film layer structure and the first through hole 11 as the hole with the stepped surface 113 as an example, the manufacturing process of the substrate 10 is explained. Assuming that the substrate 10 includes the first polyimide layer 12, the protective film layer 13 and the second polyimide layer 14, in this case, the first polyimide layer 12 as shown in FIG. 9 is manufactured on the provided glass substrate 60; the protective film layer 13 as shown in FIG. 10 is manufactured on the first polyimide layer 12; and the second polyimide layer 14 as shown in FIG. 11 is manufactured on the protective film layer 13 (the hole wall of the first through hole 111 protrudes beyond the hole wall of the second through hole 112), thereby obtaining the substrate 10 with the first through hole 11 (with the stepped surface 113).

In the above-mentioned step S820, the process of manufacturing the driving layer 20 with the second through hole 21 and forming the first sub-light-absorbing structure 1061 on the hole wall of the second through hole 21 may be: according to a prefabricated pattern of each film layer of the driving layer 20, while manufacturing the driving layer 20 with the second through hole 21, forming the first sub-light-absorbing structure 1061 on the hole wall of the second through hole 21 (the planar layer 28 included in the driving layer 20 is a black material layer, and the planar layer 28 includes the first sub-light-absorbing structure 1061 formed on the hole wall of the second through hole 21).

In addition, in the case where the second through hole 21 is formed in the stacked buffer layer 22, gate insulation layer 24, interlayer insulation layer 26 and planar layer 28, at least one of the buffer layer 22, the gate insulation layer 24, the interlayer insulation layer 26 and the source-drain metal layer 27 includes the blocking structure formed on the hole wall of the second through hole 21. In this case, the first sub-light-absorbing structure 1061 is formed on the surface of the blocking structure.

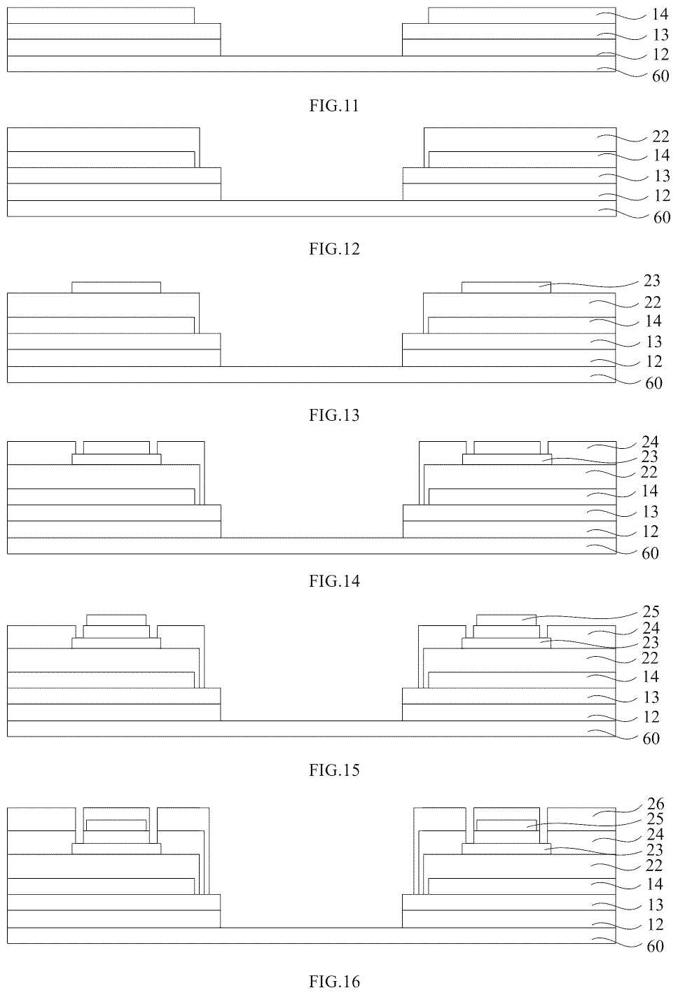

Next, taking forming the blocking structure and the first sub-light-absorbing structure 1061 while manufacturing the driving layer 20 as an example, the manufacturing process of the driving layer 20 is explained. In combination with the above, the driving layer 20 includes the buffer layer 22, the active layer 23, the gate insulation layer 24, the gate metal layer 25, the interlayer insulation layer 26, the source-drain metal layer 27 and the planar layer 28. In this case, the buffer layer 22 as shown in FIG. 12 is manufactured on the second polyimide layer 14 according to a prefabricated pattern of the buffer layer 22, and the buffer layer 22 covers the hole wall of the second through hole 112 and is connected to the protective film layer 13. The active layer 23 as shown in FIG. 13 is manufactured on the buffer layer 22 according to a prefabricated pattern of the active layer 23. The gate insulation layer 24 as shown in FIG. 14 is manufactured on the active layer 23 according to a prefabricated pattern of the gate insulation layer 24, and the gate insulation layer 24 covers the hole wall of the buffer layer 22 and is connected to the protective film layer 13. The gate metal layer 25 as shown in FIG. 15 is manufactured on the gate insulation layer 24 according to a prefabricated pattern of the gate metal layer 25. The interlayer insulation layer 26 as shown in FIG. 16 is manufactured on the gate metal layer 25 according to a prefabricated pattern of the interlayer insulation layer 26, the interlayer insulation layer 26 covers the hole wall of the gate insulation layer 24 and is connected to the protective film layer 13. The source-drain metal layer 27 as shown in FIG. 17 is manufactured on the interlayer insulation layer 26 according to a prefabricated pattern of the source-drain layer, the source-drain metal layer 27 covers the hole wall of the interlayer insulation layer 26 and is connected to the protective film layer 13. In this case, the buffer layer 22, the gate insulation layer 24, the interlayer insulation layer 26, and the source-drain metal layer 27 are provided with the blocking structure. The planar layer 28 as shown in FIG. 18 is manufactured on the source-drain metal layer 27 according to a prefabricated pattern of the planar layer 28, the planar layer 28 is made of a black material, the planar layer 28 covers the hole wall of the source-drain metal layer 27, and is in contact with the protective film layer 13, so as to obtain the driving layer 20 with the second through hole 21 and the first sub-light-absorbing structure 1061 formed on the hole wall of the second through hole 21.

For the driving layer 20 manufactured by the above process, the buffer layer 22 covers the hole wall of the second polyimide layer 14, the gate insulation layer 24 covers the hole wall of the buffer layer 22, the interlayer insulation layer 26 covers the hole wall of the gate insulation layer 24, and the source-drain metal layer 27 covers the hole wall of the interlayer insulation layer 26 to form a stepped cylindrical blocking structure, and the planar layer 28 covers the hole wall of the source-drain metal layer 27 to form the first sub-light-absorbing structure 1061.

In the above step S830, the process of manufacturing the light-emitting layer 30 with the third through hole 31 may be: according to a prefabricated pattern of each film layer of the light-emitting layer 30, completing the manufacturing of the light-emitting layer 30 with the third through hole 31.

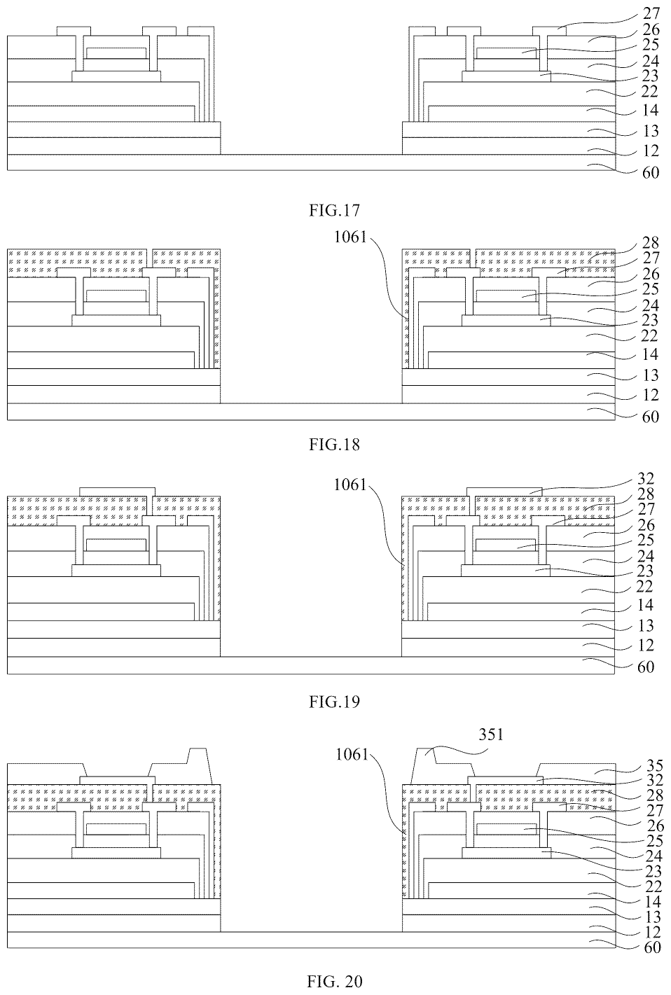

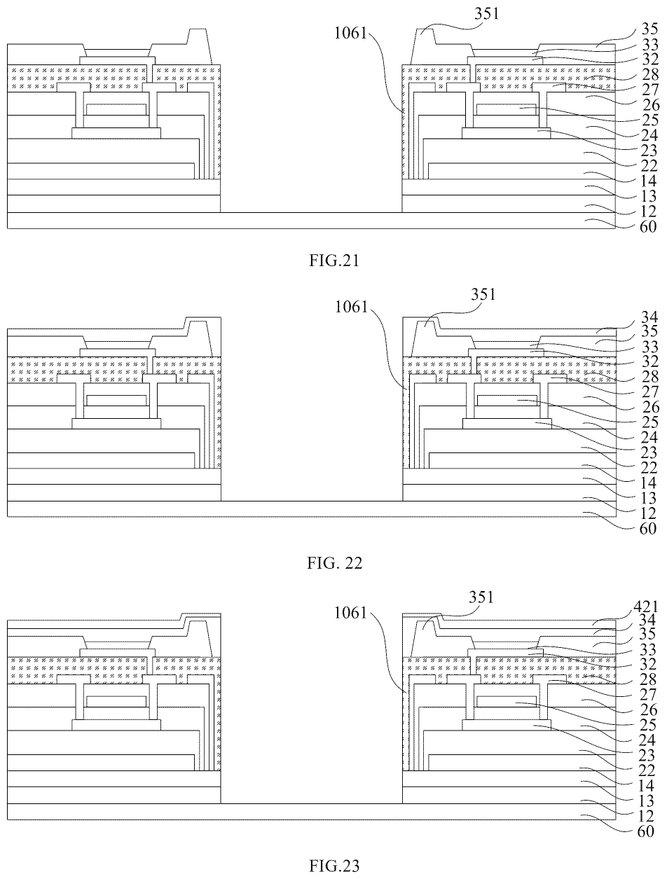

For example, according to a prefabricated pattern of the first electrode 32, the first electrode 32 as shown in FIG. 19 is formed on the side of the driving layer 20 away from the substrate 10; according to a prefabricated pattern of the pixel definition layer 35, the pixel definition layer 35 as shown in FIG. 20 is manufactured on the first electrode 32; according to a prefabricated pattern of the light-emitting function layer 33, the light-emitting function layer 33 as shown in FIG. 21 is manufactured on the pixel definition layer 35; according to a prefabricated pattern of the second electrode 34, the second electrode 34 as shown in FIG. 22 is manufactured on the light-emitting function layer 33, so as to obtain the light-emitting layer 30 with the third through hole 31.

In some embodiments, in the above step S140, the functional film layer 40 includes the thin film encapsulation layer 42, the touch function layer 43, etc. In this case, after the above step S830 is completed, it is necessary to manufacture each functional film layer 40 on the light-emitting layer 30 to obtain the display panel 100 including the substrate 10, the driving layer 20, the light-emitting layer 30, and the functional film layer 40.

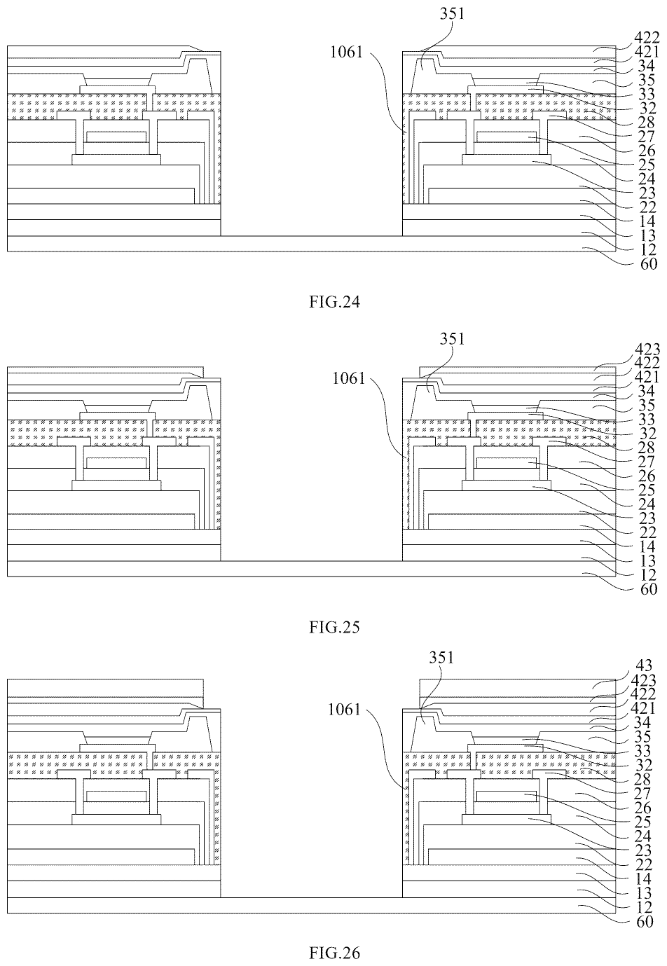

Taking the display panel 100 including the thin film encapsulation layer 42 as an example, according to a prefabricated pattern of the first inorganic encapsulation layer 421, the first inorganic encapsulation layer 421 as shown in FIG. 23 is manufactured on the side of the light-emitting layer 30 away from the substrate 10; according to a prefabricated pattern of the organic encapsulation layer 422, the organic encapsulation layer 422 as shown in FIG. 24 is manufactured on the first inorganic encapsulation layer 421; and according to a prefabricated pattern of the second inorganic encapsulation layer 423, the second inorganic encapsulation layer 423 as shown in FIG. 25 is manufactured on the organic encapsulation layer 422, so as to obtain the thin film encapsulation layer 42 with the fourth through hole 41.

In some embodiments, when the organic encapsulation layer 422 is manufactured, due to the fluidity of the organic encapsulation layer 422, in order to prevent the organic encapsulation layer 422 from flowing into the third through hole 31, in the above-mentioned step S830, when the pixel definition layer 35 of the light-emitting layer 30 is manufactured, as shown in FIG. 20, a convex ring 351 surrounding the third through hole 31 may be formed by the pixel definition layer 35, thereby blocking the organic encapsulation layer 422 through the convex ring 351 to prevent the organic encapsulation layer 422 from flowing into the third through hole 31.

Continuing with the example of the display panel 100 including the touch function layer 43, the touch function layer 43 as shown in FIG. 26 may be manufactured on the thin film encapsulation layer 42 according to a prefabricated pattern of the touch function layer 43 to obtain the touch function layer 43 with the fourth through hole 41.

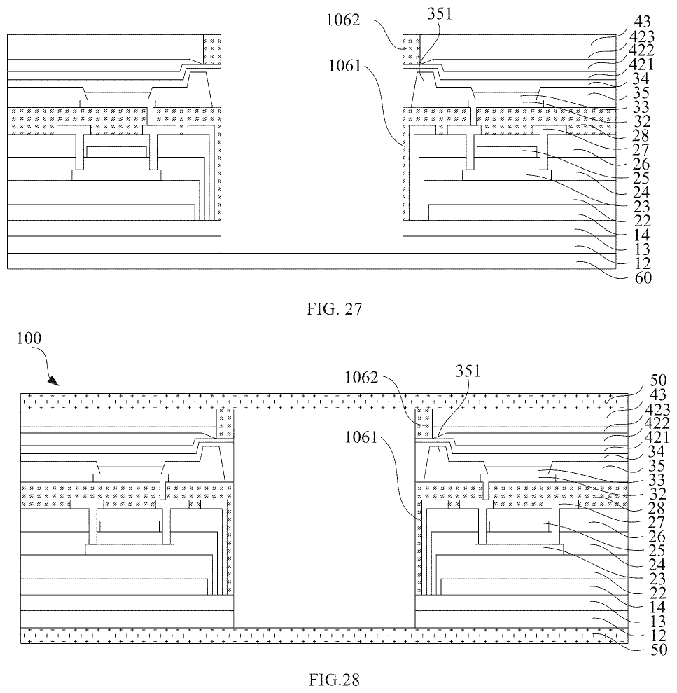

It should be noted that after the manufacturing of the functional film layer 40 with the fourth through hole 41 is completed, taking the display panel 100 including the thin film encapsulation layer 42 and the touch function layer 43 as an example, the black matrix layer is manufactured on the side of the touch function layer 43 away from the substrate, and the second sub-light-absorbing structure 1062 in the same layer as the black matrix layer as shown in FIG. 27 is formed on the hole wall of the fourth through hole 41.

In addition, in combination with the above-mentioned case of using the glass substrate 60 as the carrier, after the manufacturing of the second sub-light-absorbing structure 1062 is completed, the glass substrate 60 can be peeled off from the substrate 10, and the light-transmitting film layers 50 as shown in FIG. 28 can be manufactured on the side of the substrate 10 away from the driving layer 20 and on the side of the functional film layer 40 away from the light-emitting layer 30, so as to block the through holes on respective film layers through the light-transmitting film layers 50, reduce the water and oxygen from penetrating into the interior of the film layer along the hole wall of the through hole to cause damage to the display panel 100 and shorten the service life.

It should be noted that although various steps of the method for manufacturing the display panel 100 in the present disclosure are described in a specific order in the figures, this is not required or implied that the steps must be performed in the specific order, or all the steps shown must be performed to achieve the desired result. Additionally or alternatively, certain steps may be omitted, multiple steps may be combined into one step, and/or one step may be decomposed into multiple steps and so on.

Embodiments of the present disclosure further provide a display device, which includes the display panel described in the above embodiments. Thus, for the display device including the above display panel, when the under-screen camera module is shooting, the formation of stray light is reduced, the light transmission effect is improved, and the clarity of the image when the camera module is shooting is ensured.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A display panel, comprising:
a light-transmitting area, comprising a plurality of first pixel units, wherein a light-transmitting hole is provided between two adjacent first pixel units, and a hole wall of the light-transmitting hole is provided with a light-absorbing structure; and
a display area, located outside the light-transmitting area and comprising a plurality of second pixel units, wherein a distribution density of the second pixel units in the display area is greater than a distribution density of the first pixel units in the light-transmitting area.

2. The display panel according to claim 1, wherein the display panel comprises:
a substrate, comprising a first through hole located in the light-transmitting area;
a driving layer, located on a side of the substrate, and comprising a second through hole located in the light-transmitting area, wherein a hole wall of the second through hole is provided with a first sub-light-absorbing structure, and a surface of the first sub-light-absorbing structure is at most flush with a hole edge of the first through hole on a side away from the driving layer;
a light-emitting layer, located on a side of the driving layer away from the substrate, and comprising a third through hole located in the light-transmitting area, wherein a hole wall of the third through hole is at most flush with the surface of the first sub-light-absorbing structure; and
a functional film layer, located on a side of the light-emitting layer away from the substrate, and comprising a fourth through hole located in the light-transmitting area, wherein a hole wall of the fourth through hole is provided with a second sub-light-absorbing structure, and a surface of the second sub-light-absorbing structure is at most flush with the hole wall of the third through hole.

3. The display panel according to claim 2, wherein the functional film layer comprises a black matrix layer, and the first sub-light-absorbing structure and the second sub-light-absorbing structure are manufactured in the same layer as the black matrix layer.

4. The display panel according to claim 2, wherein the driving layer comprises a planar layer, the planar layer is a black material layer, and the planar layer is manufactured in the same layer as the first sub-light-absorbing structure, or the light-emitting layer comprises a pixel definition layer, the pixel definition layer is the black material layer, and the pixel definition layer is manufactured in the same layer as the first sub-light-absorbing structure; and
the functional film layer comprises a black matrix layer, and the second sub-light-absorbing structure is manufactured in the same layer as the black matrix layer.

5. The display panel according to claim 4, wherein the pixel definition layer is provided with a convex ring surrounding the second through hole.

6. The display panel according to claim 2, wherein the driving layer comprises a buffer layer, an active layer, a gate insulation layer, a gate metal layer, an interlayer insulation layer and a source-drain metal layer which are sequentially distributed in a direction away from the substrate; and
at least one of the buffer layer, the gate insulation layer, the interlayer insulation layer, and the source-drain metal layer comprises a blocking structure formed on the hole wall of the second through hole and surrounding the first sub-light-absorbing structure.

7. The display panel according to claim 6, wherein the first through hole is provided with a stepped surface facing the driving layer, and the blocking structure is supported on the stepped surface.

8. The display panel according to claim 1, wherein the display panel further comprises a light-transmitting film layer at least located on a display side of the display panel, and the light-transmitting hole is covered by the light-transmitting film layer.

9. A method for manufacturing a display panel, wherein the display panel comprises a light-transmitting area and a display area, and the method comprises:
manufacturing a substrate, wherein the substrate comprises a first through hole located in the light-transmitting area;
manufacturing a driving layer on a side of the substrate, wherein the driving layer comprises a second through hole located in the light-transmitting area, a hole wall of the second through hole is provided with a first sub-light-absorbing structure, and a surface of the first sub-light-absorbing structure is at most flush with a hole edge of the first through hole on a side away from the driving layer;
manufacturing a light-emitting layer on a side of the driving layer away from the substrate, wherein the light-emitting layer comprises a third through hole located in the light-transmitting area, and a hole wall of the third through hole is at most flush with the surface of the first sub-light-absorbing structure; and
manufacturing a functional film layer on a side of the light-emitting layer away from the substrate, wherein the functional film layer comprises a fourth through hole located in the light-transmitting area, a hole wall of the fourth through hole is provided with a second sub-light-absorbing structure, and a surface of the second sub-light-absorbing structure is at most flush with the hole wall of the third through hole.

10. The method according to claim 9, wherein manufacturing the driving layer on the side of the substrate comprises:
sequentially manufacturing a buffer layer, an active layer, a gate insulation layer, a gate metal layer, an interlayer insulation layer, a source-drain metal layer and a planar layer on the side of the substrate, wherein the second through hole is formed in the stacked buffer layer, gate insulation layer, interlayer insulation layer and planar layer, and at least one of the buffer layer, the gate insulation layer, the interlayer insulation layer and the source-drain metal layer comprises a blocking structure formed on the hole wall of the second through hole, the planar layer is a black material layer, and a surface of the blocking structure is provided with the first sub-light-absorbing structure manufactured in the same layer as the planar layer.

11. A display device, comprising a display panel, wherein the display panel comprises:
a light-transmitting area, comprising a plurality of first pixel units, wherein a light-transmitting hole is provided between two adjacent first pixel units, and a hole wall of the light-transmitting hole is provided with a light-absorbing structure; and
a display area, located outside the light-transmitting area and comprising a plurality of second pixel units, wherein a distribution density of the second pixel units in the display area is greater than a distribution density of the first pixel units in the light-transmitting area.

12. The display device according to claim 11, wherein the display panel comprises:
a substrate, comprising a first through hole located in the light-transmitting area;
a driving layer, located on a side of the substrate, and comprising a second through hole located in the light-transmitting area, wherein a hole wall of the second through hole is provided with a first sub-light-absorbing structure, and a surface of the first sub-light-absorbing structure is at most flush with a hole edge of the first through hole on a side away from the driving layer;
a light-emitting layer, located on a side of the driving layer away from the substrate, and comprising a third through hole located in the light-transmitting area, wherein a hole wall of the third through hole is at most flush with the surface of the first sub-light-absorbing structure; and
a functional film layer, located on a side of the light-emitting layer away from the substrate, and comprising a fourth through hole located in the light-transmitting area, wherein a hole wall of the fourth through hole is provided with a second sub-light-absorbing structure, and a surface of the second sub-light-absorbing structure is at most flush with the hole wall of the third through hole.

13. The display device according to claim 12, wherein the functional film layer comprises a black matrix layer, and the first sub-light-absorbing structure and the second sub-light-absorbing structure are manufactured in the same layer as the black matrix layer.

14. The display device according to claim 12, wherein the driving layer comprises a planar layer, the planar layer is a black material layer, and the planar layer is manufactured in the same layer as the first sub-light-absorbing structure, or the light-emitting layer comprises a pixel definition layer, the pixel definition layer is the black material layer, and the pixel definition layer is manufactured in the same layer as the first sub-light-absorbing structure; and
the functional film layer comprises a black matrix layer, and the second sub-light-absorbing structure is manufactured in the same layer as the black matrix layer.

15. The display device according to claim 14, wherein the pixel definition layer is provided with a convex ring surrounding the second through hole.

16. The display device according to claim 12, wherein the driving layer comprises a buffer layer, an active layer, a gate insulation layer, a gate metal layer, an interlayer insulation layer and a source-drain metal layer which are sequentially distributed in a direction away from the substrate; and
at least one of the buffer layer, the gate insulation layer, the interlayer insulation layer, and the source-drain metal layer comprises a blocking structure formed on the hole wall of the second through hole and surrounding the first sub-light-absorbing structure.

17. The display device according to claim 16, wherein the first through hole is provided with a stepped surface facing the driving layer, and the blocking structure is supported on the stepped surface.

18. The display device according to claim 11, wherein the display panel further comprises a light-transmitting film layer at least located on a display side of the display panel, and the light-transmitting hole is covered by the light-transmitting film layer.
